(19) United States
(12) Patent Application Publication
(10) Pub. No.: US 2025/0245403 A1
(43) Pub. Date: Jul. 31, 2025

(54) METHOD AND DEVICE WITH SEMICONDUCTOR DEVICE QUALITY PREDICTION

(71) Applicant: Samsung Electronics Co., Ltd., Suwon-si (KR)

(72) Inventors: Deokwon SIM, Suwon-si (KR); Sangwon BAEK, Suwon-si (KR); Kaeweon YOU, Suwon-si (KR); Hyunsoo LEE, Suwon-si (KR); Byungyong CHOI, Suwon-si (KR); Jonghyun KIM, Suwon-si (KR); Jongik HONG, Suwon-si (KR)

(73) Assignee: Samsung Electronics Co., Ltd., Suwon-si (KR)

(21) Appl. No.: 19/042,933

(22) Filed: Jan. 31, 2025

(30) Foreign Application Priority Data
Jan. 31, 2024 (KR) 10-2024-0015315
May 14, 2024 (KR) 10-2024-0063092

(51) Int. Cl. G06F 30/27; G06N 20/00

(52) U.S. Cl. CPC G06F 30/27; G06N 20/00

(57) ABSTRACT

A method for predicting quality of a workpiece includes: obtaining optical emission spectroscopy (OES) raw data of the workpiece, the OES raw data having a time dimension and a wavelength dimension; selecting, in the wavelength dimension, a first portion of the OES raw data that falls within wavelength ranges selected based on a material used in a process of producing the workpiece; selecting, in the time dimension, a second port of the OES raw data that falls within a time range corresponding to a specific step of the process, where the specific step is to be analyzed; generating tokens by grouping the selected portions of the OES raw data; and training a model with the tokens.

### CROSS-REFERENCE TO RELATED APPLICATIONS

This application claims priority to and the benefit of Korean Patent Application No. 10-2024-0015315 filed in the Korean Intellectual Property Office on Jan. 31, 2024, and Korean Patent Application No. 10-2024-0063092 filed in the Korean Intellectual Property Office on May 14, 2024, the entire contents of all of which are incorporated herein by reference.

### BACKGROUND

### 1. Field

The present disclosure relates to a method and device for predicting quality of a semiconductor device.

### 2. Description of Related Art

Optical emission spectroscopy (OES) is a technology that analyzes the composition or characteristic of a material using the light emitting characteristic of the material. OES uses a high-resolution optical device measures the intensity (or strength) of the wavelengths of light emitted by the elements in a sample and to analyze determine the types (e.g., which elements) and contents (e.g., how much) of the elements in the sample. Specifically, when a high-energy electrical source (e.g., a high voltage spark or arc) is applied to the sample, electrons in the sample's atoms absorb energy and become excited and when the excited electrons return to a stable state the release energy in the form of light. The light emitted in this way has different wavelengths, and the corresponding wavelengths may be the characteristic of the elements that make up the sample. That is, as with other spectroscopy techniques, each element has a distinct fingerprint/characteristic of discrete wavelength intensities; with OES those wavelengths generally span the red to ultraviolet spectrum. For example, iron can emit over 6000 distinct wavelengths. Therefore, the distribution of light wavelengths (and the respective intensities) emitted by a sample of material may be obtained as a spectrum and then analyzed through OES-related signal processing techniques to accurately determine the type and content of the elements that make up the material of the sample.

### SUMMARY

Some embodiments and examples described herein may for predicting quality of a semiconductor device for preventing loss or distortion of information by using optical emission spectroscopy (OES) raw data, and performing semiconductor process analysis and quality prediction through a model to which a structure of OES data including time, wavelength, and intensity is reflected.

In one general aspect, a method for predicting quality of a workpiece includes: obtaining optical emission spectroscopy (OES) raw data of the workpiece, the OES raw data having a time dimension and a wavelength dimension; selecting, in the wavelength dimension, a first portion of the OES raw data that falls within wavelength ranges selected based on a material used in a process of producing the workpiece; selecting, in the time dimension, a second port of the OES raw data that falls within a time range corresponding to a specific step of the process, where the specific step is to be analyzed; generating tokens by grouping the selected portions of the OES raw data; and training a model with the tokens.

The selected wavelength ranges may correspond to OES responsivity of the material.

The selecting of the first portion of the OES raw data may further include selecting OES raw data having OES intensity greater than a predetermined reference.

The generating of the tokens may include grouping the selected portions of the OES raw data by dividing the second portion of the OES data into time sections with a predetermined size.

The generating of the tokens may include grouping the OES raw data so that one token corresponds to one wavelength range of the first portion of the OES raw data and corresponds to one time section of the second portion of the OES raw data.

The generating of the tokens may include grouping the OES raw data so that one token corresponds to wavelength ranges of the first portion of the OES raw data and corresponds to one time section of the second portion of the OES raw data.

The time range may be selected by determining whether a data amount belonging to a time range corresponding to the specific step of the process to be analyzed is greater than a predetermined threshold value in the OES raw data, and when it is determined that the data amount is greater than the threshold value, generating the second portion of the OES data by performing a sampling or a moving average in the time dimension of the OES raw data.

The method may further include obtaining a yield of the specific step to be analyzed, and determining whether the yield is higher than a predetermined reference value, wherein the generating of tokens may include when the yield is determined to be higher than a reference value, adding an extended region to a wavelength range corresponding to one token, additionally dividing the time section corresponding to the one token into a detailed time section, and grouping the OES raw data so that the one token corresponds to the wavelengths to which the extended region is added and the additionally divided time section.

The model may include a transformer model.

The specific step to be analyzed may include an etching process or a deposition process.

In another general aspect, a method includes: obtaining optical emission spectroscopy (OES) raw data; receiving a first model trained by a first method and a second model provided by a second method differing from the first method; selecting a model to be used in quality prediction from among the first model and the second model by using the OES raw data; and predicting quality of a wafer produced by a semiconductor process by using the selected model, wherein the first model is trained by tokens generated by grouping the OES raw data according to wavelength ranges selected based on a material used in the semiconductor process and a time range selected to correspond to a specific process step of the semiconductor process, the specific process step to be analyzed during the semiconductor process.

The selecting of the model to be used in quality prediction may include inputting the OES raw data to the first model and the second model to generate a first quality index predicted value and a second quality index predicted value, respectively; generating a first coefficient of determination based on a quality index measured value and the first quality index predicted value; generating a second coefficient of determination based on a quality index measured value and the second quality index predicted value; comparing sizes of the first coefficient of determination and the second coefficient of determination; and selecting the first model as the model to be used in quality prediction when the first coefficient of determination is greater than the second coefficient of determination, and selecting the second model as the model to be used in quality prediction in other cases.

The grouping of the OES raw data may include dividing the time range into a time section with a predetermined size, and grouping the OES raw data so that one token corresponds to one wavelength and the time section.

The grouping of the OES raw data may include dividing the time range into a time section with a predetermined size, and grouping the OES raw data so that one token corresponds to wavelengths and the time section.

The second model may be trained using OES data processed by applying self-normalization, calibration, or an intensity average ratio at a time interval.

In another general aspect, a device for predicting quality of a workpiece includes instructions loaded on a memory device through one or more processors, wherein the memory device provides a model based on optical emission spectroscopy (OES) raw data, and the instructions select a subset of the OES raw data that (i) is within wavelength ranges pre-associated with a material used during a process of producing the workpiece and that (ii) is within a timespan corresponding to a specific step of the process, generates tokens according to the subset of the OES raw data, and trains the model with the tokens.

The wavelength ranges may be defined according to wavelengths of OES responsiveness of the material.

The wavelength ranges may be selected based on having intensities greater than a predetermined reference.

The generating of the tokens may include dividing the time range into a time section with a predetermined size, and grouping the subset of OES raw data so that one token corresponds to one wavelength range and the time section.

The generating of the tokens may include dividing the time range into a time section with a predetermined size, and grouping the subset of OES raw data so that one token corresponds to wavelength ranges and the time section.

Other features and aspects will be apparent from the following detailed description, the drawings, and the claims.

### BRIEF DESCRIPTION OF THE DRAWINGS

FIG. 1 shows a device for predicting quality of a semiconductor device according to one or more embodiments.

FIGS. 2 to 4 show a device for predicting quality of a semiconductor device according to one or more embodiments.

FIG. 5 shows a method for training a model to predict quality of a semiconductor device according to one or more embodiments.

FIG. 6 shows a device for predicting quality of a semiconductor device according to one or more embodiments.

FIG. 7 shows a method for predicting quality of a semiconductor device according to one or more embodiments.

FIG. 8 shows data processing of a device for predicting quality of a semiconductor device according to one or more embodiments.

FIG. 9 shows data processing of a device for predicting quality of a semiconductor device according to one or more embodiments.

FIG. 10 shows a computing device according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

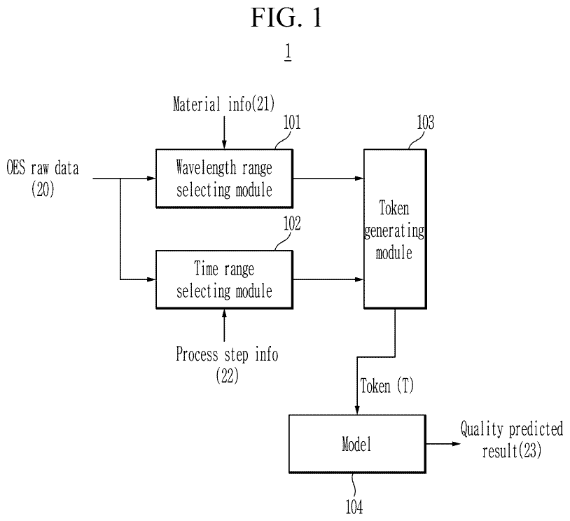

FIG. 1 shows a device 1 for predicting quality of a semiconductor device according to one or more embodiments.

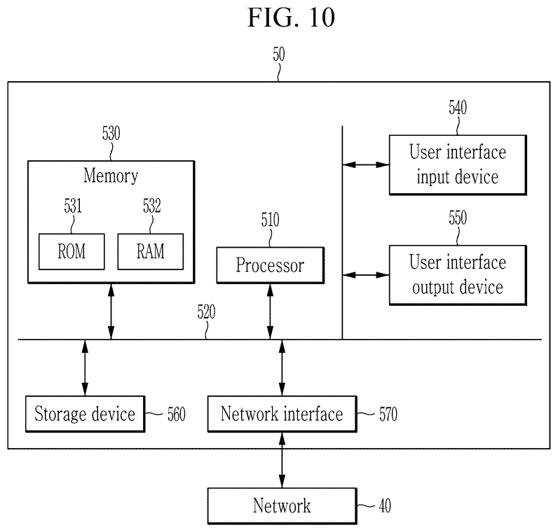

Referring to FIG. 1, the device 1 for predicting quality of a semiconductor device 1 may execute a program (instructions) loaded on a memory device through one or more processors. For example, the device 1 for predicting quality of a semiconductor device may be realized with a computing device 50 described below with reference to FIG. 10. In this case, the one or more processors may be the processor 510 of the computing device 50, and the at memory device may be the memory 520 of the computing device 50. The instructions may be executed by the at least one processor to perform the functions described herein. Such functions may be implemented as (and referred to as) “modules” to logically distinguish the functions from each other, however any arrangement or configuration of modules may be used to implement the functions.

The device 1 for predicting quality of a semiconductor device (also referred to as a “quality predicting device”) may train a model 104 (e.g., a neural network model) based on optical emission spectroscopy (OES) data and may use the trained model 104 to perform a semiconductor process analysis and quality prediction.

OES measurement may be used to analyze the light of plasma used in an etching process and a deposition process in a semiconductor manufacturing process, and generally speaking, the OES data obtained through the OES measurement may be used to manage states of the respective processes and quality of the products (e.g., wafers). To achieve this, methods of using machine learning (e.g., neural networks) for processing and/or analyzing the OES data may be considered.

In connection to this, the OES raw data 20, which may have a time dimension and a wavelength dimension (i.e., wavelength intensities measured over time) may be filtered and transformed in order to be applied to the model 104, a method for standardizing the OES data may be used, which may involve (i) normalization, (ii) calculating eigenvalues and eigenvectors of a covariance matrix through a principal component analysis (PCA), (iii) arranging the eigenvectors in order of the eigenvalues (e.g., from the largest to smallest). The thus-transformed OES data corresponding to a primary component may be applied to the model 104.

Alternatively, a method for applying preprocessed OES data to the model 104 may involve (i) self-normalization for normalizing the OES data by comparing the intensity of a measured signal and average signal intensity of the wavelength section including an internal standard or a signal, (ii) calibration for obtaining OES data on a component that participated in the actual reaction considering a component (e.g., inert gas) that did not participate in the actual process reaction in the semiconductor process, or an intensity average ratio determined at time intervals for distinguishing the OES signal by time intervals, (iii) finding a mean value of the OES data with respect to the time intervals, and (iv) using the same to analyze changes of the intensity of the OES signal in the semiconductor process.

However, because these methods do not directly use OES raw data but rather use preprocessed data OES data as described above, which may be traces or signals corresponding only to specific wavelengths, loss and distortion of information in the OES data may occur. That is to say, pre-processing of OES data may result in OES information loss and OES information distortion which may in turn reduce accuracy in the analysis and quality prediction of the semiconductor process using OES data. Particularly, the impact of such information loss and information distortion on the OES data may be significant because the analysis methods used for semiconductor processes is complex and the level of precision of quality prediction may be high, which puts a premium on precise results (in other words, model-based OES analysis tends to be sensitive to the quality of input OES data). In addition, the obtained OES raw data is generally 3-dimensional data including time, wavelength, and intensity, but model-based analysis methods may have difficulty in capturing the time and wavelength structure in model learning/training.

Various implementations of the quality predicting device 1 may use the OES raw data in ways that reduce loss or distortion of OES information, and may perform semiconductor process analysis and quality prediction with a model that reflects the time, wavelength, and intensity structure of OES data. For this purpose, the quality predicting device 1 may obtain the OES raw data and may execute a program having functions corresponding to a wavelength range selecting module 101, a time range selecting module 102, and a token generating module 103.

The wavelength range selecting module 101 may select (or filter, as a kind of band-pass filter) wavelength ranges (or particular wavelengths) of the OES raw data 200 based on the type of material used during the semiconductor process from which the OES raw data 20 was obtained. That is, the wavelength range selecting module 101 may receive the OES raw data 20 and material information 21, and may select (or pass through), from the OES raw data 20, OES raw data in the wavelength ranges that correspond the material information 21. In other words, the wavelength range selection module 101 may filter out (remove) from the OES raw data 20 any data that does not fall within the wavelength ranges pre-associated with the target material.

In some embodiments, the wavelength range selecting module 101 may select a predesignated wavelength ranges associated with the particular type of material used during the semiconductor process. In this case, material information 21 inputted to the wavelength range selecting module 101 may include information about a material name/type/label and wavelength ranges of the light emitted from the material's reaction with plasma of the semiconductor process. The selected wavelength range(s) may be used for material-specific training of the model 104.

The materials used in the semiconductor process may include, as non-limiting examples, nitrogen (N₂), oxygen (O₂), and argon (Ar). The wavelength ranges of the light emitted from the reaction with plasma may be different from each other for the respective materials. For example, light emitted from argon with the wavelengths of 420 nm, 675.5 nm, 738.5 nm, 763.5 nm, and 772.5 nm may be detected through OES measurement. Light emitted from oxygen with the wavelengths of 244.5 nm, 297 nm, 563 nm, 685.5 nm, 748 nm, and 777.5 nm may be detected through OES measurement. In other words, different wavelengths of light detected through OES measurement for the respective materials used in the process may be used for training the model 104, and the wavelength values of light detected through the OES for the respective materials may be provided to the wavelength range selecting module 101 as the material information 21, which then passes through the corresponding parts of the raw OES data 20.

In some embodiments, the wavelength range selecting module 101 may select wavelength range(s) whose OES intensity/intensities of the material used during the semiconductor process exceed(s) a predetermined reference (e.g., by a ratio of magnitude). In this case, the material information 21 input to the wavelength range selecting module 101 may include the material name (or type, etc.) and information about the point where the OES intensity of the light emitted from the reaction with plasma is strong (which may allow filtering out of other wavelengths).

More specifically, there may be wavelengths with high OES intensity for each material used in the semiconductor process, and these wavelengths may correspond to changes in energy level (magnitude of a wavelength) due to plasma. For example, in the case of carbon fluoride (CF) or carbon monoxide (CO), light energy with the wavelengths including 218.5 nm, 247.5 nm, and 266 nm may be emitted, and points with strong OES intensity may appear among the measured wavelengths. In other words, wavelengths with large OES intensity values for the respective materials used in the process may be used for training the model 104, and the OES intensity values for the respective materials may be provided to the wavelength range selecting module 101 as (or with) the material information 21, thus informing the training process or inference process, as the case may be.

The time range selecting module 102 may select (pass-passthrough) a part of the OES raw data 20 that fills within a time range corresponding to the process step to be analyzed during the semiconductor process. More specifically, the time range selecting module 101 may receive the OES raw data 20 and process step information 22 (information about which process step corresponds to the OES raw data 20), and may select (pass-through) the OES raw data 20 based on the same. Here, the semiconductor production process step that is to be analyzed may be an etching process or a deposition process, as non-limiting examples, and the process step information 22 may include identification information identifying the process step (e.g., an identifier that uniquely identifies the process step). Particularly, the etching process or the deposition process may include detailed steps distinguished in detail. For example, in the etching process or the deposition process, detailed process steps for monitoring the process or predicting the product quality may be distinguished or defined. In this case, the process step information 22 may include identification information for identifying the detailed process steps.

The token generating module 103 may generate tokens (T) by grouping into tokens the OES raw data (spectrum data) passed through (selected) by (i) the wavelength range selecting module 101 and (ii) the OES raw data selected (passed-through) by the time range selecting module 102. Here, the tokens (T) may represent data generated by respective divisions of the OES raw data including time, wavelength, and intensity into the wavelength range selected by the wavelength range selecting module 101, and a plurality of regions in a same shape (dimensions) established with reference to the time range selected by the time range selecting module 102.

The token generating module 103 may group the OES raw data by dividing the time range of OES raw data selected by the time range selecting module 102 into time sections with a predetermined duration. For example, the token generating module 103 may group the passed-through OES raw data by equally dividing the passed-through OES raw data in the selected time range into time sections of 10 seconds.

In some embodiments, the token generating module 103 may group the OES raw data so that one token (T) corresponds to one wavelength and time section. Here, the one wavelength may be a wavelength predetermined for the material used during the semiconductor process, or may be a wavelength at which the OES intensity of the material used during the semiconductor process exceeds the predetermined reference.

In some embodiments, the token generating module 103 may group the OES raw data so that one token (T) corresponds to a wavelength-time section. Here, the wavelength sections may be, for example, wavelength sections that are within a predetermined range (e.g., 2 nm) of the predetermined wavelengths of the material used in the semiconductor process, or wavelength sections within a predetermined range (e.g., 2 nm) of a wavelength in which OES intensity of the material used in the semiconductor process is greater than a predetermined reference. In some embodiments, wavelength sections may be a combination of the aforementioned types of sections.

The quality predicting device 1 may train the model 104 with the tokens (T) generated by the token generating module 103. The model 104 may, for example, include a transformer model. In this case, each token (T) may be embedded into a corresponding vector (e.g., an embedding vector) of the same dimension which may then be provided to the transformer model. The transformer model may thus collect information from various parts of the input data and may learn rich expressions based on an attention mechanism. That is, the model 104 may model the correlation between grouped data with the quality of the wafer while maintaining the wavelength and time structure/information of the OES raw data. The model 104 may output a predicted quality result 23 of the semiconductor device inferred from the selected and transformed raw OES data.

According to the present embodiment, the raw OES data is used in a way that reduces loss or distortion of information, and further accurate information on the process may be reflected, and hence, quality and accuracy of the products and system having high complexity and requiring a precise process may be increased. In addition, the accuracy of the predicted qualities of the semiconductor devices may be improved by performing a semiconductor process analysis and quality prediction through the model that reflects the structure/information of the raw OES data including time, wavelength, and intensity.

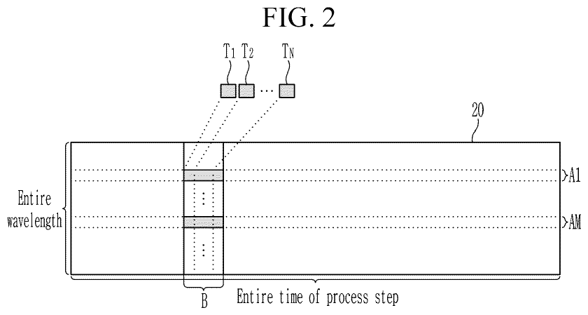

FIG. 2 to FIG. 4 show a device for predicting quality of a semiconductor device according to one or more embodiments.

Referring to FIG. 2, a sampling of OES raw data 20 is shown. The vertical axis represents wavelength and the horizontal axis represents time. A data section (cell or unit) defined over a given wavelength section and a given time section may contain corresponding measured intensities. As noted, the device 1 for predicting quality of a semiconductor device may acquire and pre-process the OES raw data 20, which may include dividing the OES raw data 20 into sections that are represented by respective tokens, as described next.

As described above, the wavelength range selecting module 101 may, based on the material known to have been used during the semiconductor process for which the OES raw data 20 was measured, select (pass-through) the OES raw data 20 within the material-corresponding wavelength ranges (A1, . . . , AM) (M is a natural number). The time range selecting module 102 may, based on the process step to be monitored or analyzed/predicted (e.g., an etching step or a deposition step), select (pass-through) the OES raw data 20 within a time range B that corresponds to that process step. The token generating module 103 may group the OES raw data 20 according to the selected wavelength ranges (A1, . . . , AM) of OES raw data and the OES raw data within the time range B, and may generate tokens (T₁, T₂, . . . , T_{N}) (N is a natural number) accordingly, as described next.

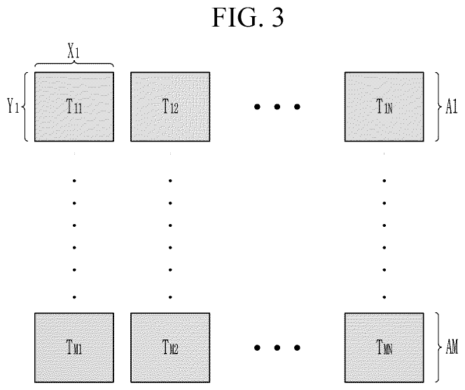

Referring to FIG. 3, the tokens (T₁₁, T₁₂, . . . , T_{1N}) (N is a natural number) may be generated by grouping the OES raw data 20 according to the wavelength range A1, and the tokens (Tᵢ₁, Tᵢ₂, . . . , T_{iN}) (i=2, . . . , M) may be generated by grouping the OES raw data 20 according to the wavelength range (Ai). Meanwhile, the tokens (T₁₁, T₂₁, . . . , T_{M1}), the tokens (T₁₂, T₂₂, . . . , T_{M2}), . . . , the tokens (T_{1N}, T_{2N}, . . . , T_{MN}) may be generated by equally dividing the time range B into predetermined time sections. The token T₁₁ may be generated in a shape with a length of X₁ and a width of Y₁, and the token T₁₁ may include OES intensity data grouped by (falling within) X₁*Y₁. In an example implementation, each token may indicate its wavelength range and time range (timespan) and may include the sum of whichever one or more discrete wavelength samples fall therewithin.

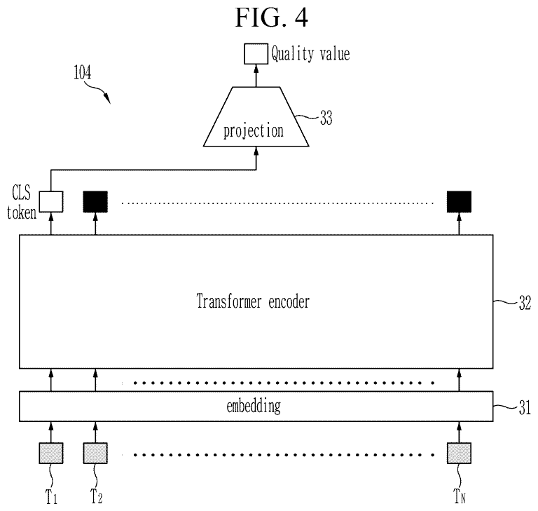

Referring to FIG. 4, tokens (T₁, T₂, . . . , T_{N}) may be input to the model 104. In detail, an embedding layer 31 may convert the tokens (T₁, T₂, . . . , T_{N}) into respective high-dimensional vectors (embedding vectors). The vectors may capture/represent meanings/information of the respective tokens (T₁, T₂, . . . , T_{N}) and may be in a form usable by the model 104. The converted vectors may be inputted to a transformer encoder 32 of the model 104. The transformer encoder 32 may include a stack/sequence of multiple encoder layers, and each layer may include a multi-head attention and a feed-forward network. According to the structure, the transformer encoder 32 may mainly learn information in the entire portions of the data output by the embedding layer 31, and may generate an output sequence including a CLS (classification) token if needed. A projection layer 33 may map the output of the model 104 to an output dimension that corresponds to a quality value as a linear conversion process used in a final step of the model 104.

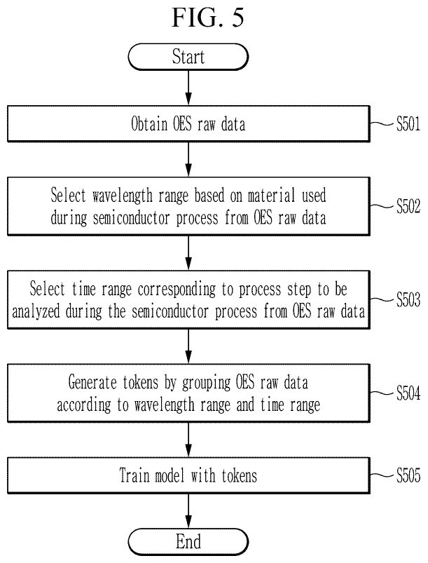

FIG. 5 shows a method for training a model (e.g., the model 104) to predict quality of a semiconductor device according to one or more embodiments.

Referring to FIG. 5, the method for predicting quality of a semiconductor device according to an embodiment may include obtaining OES raw data (S501); selecting a OES raw data in wavelength ranges (or wavelengths/wavebands) based on (corresponding to) a material used during the process step (of the semiconductor process) that is to be analyzed; selecting OES raw data within a time range corresponding to the process step that is to be analyzed during the semiconductor process; generating tokens by grouping the selected OES raw data according to the wavelength range and the time range (S504); and training the model with the tokens (S505). The training may involve, for example, minimizing loss (e.g., by gradient descent) between quality values predicted/inferred from the OES raw data and respective ground-truth labels of the ground truth data.

For more detail about the method for predicting quality of a semiconductor device, the description of the embodiments described in this specification may be referred to.

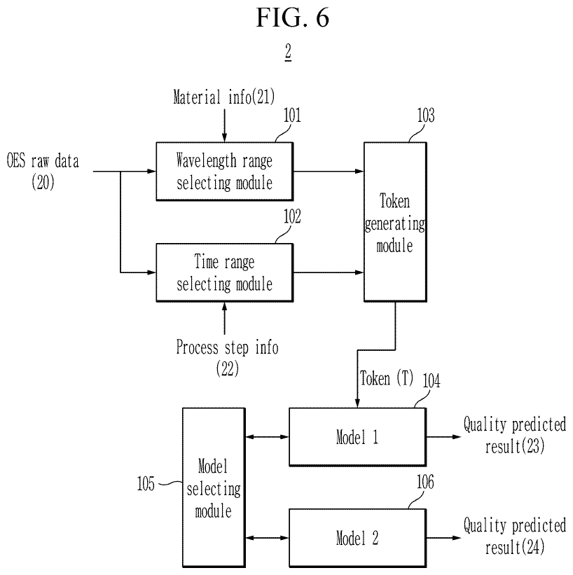

FIG. 6 shows a device for predicting quality of a semiconductor device according to one or more embodiments.

Referring to FIG. 6, the device for predicting quality of a semiconductor device 2 may obtain the OES raw data, and may execute a program for performing functions corresponding to the wavelength range selecting module 101, the time range selecting module 102, the token generating module 103, and a model selecting module 105.

The wavelength range selecting module 101 may select the wavelength range based on the material used during the semiconductor process. That is, the wavelength range selecting module 101 may receive the OES raw data 20 and the material information 21, and may select the wavelength range from the OES raw data 20 based on the same.

The time range selecting module 102 may select the time range corresponding to the process step to be analyzed during the semiconductor process from the obtained OES raw data 20. That is, the time range selecting module 101 may receive the OES raw data 20 and the process step information 22, and may select the time range from the OES raw data 20 based on the same.

The token generating module 103 may generate the tokens (T) by grouping the OES raw data according to the wavelength range selected by the wavelength range selecting module 101 and the time range selected by the time range selecting module 102.

The model selecting module 105 may receive the first model 104 trained by a first method and a second model 106 trained by a second method that is different from the first method. The first model 104 may be trained according to the first method trained with the tokens (T) generated by the token generating module 103. That is, the first model may be trained with the tokens (T) generated by grouping the OES raw data 20 according to the wavelength range selected based on the material used during the semiconductor process and the time range selected to correspond to the process step to be analyzed during the semiconductor process. Meanwhile, the second model 106 may be trained according to the second method, which is trained using the same OES data processed by applying the earlier-mentioned self-normalization, calibration, or the intensity average ratio at a time interval.

The model selecting module 105 may select the model to be used for quality prediction from among the first model 104 and the second model 106 by using the OES raw data. The quality predicting device 1 may predict the quality of wafers after the semiconductor process by using the model selected by the model selecting module 105. In detail, when the model selecting module 105 selects the first model 104, the first model 104 may output a quality predicted result 23 of the semiconductor device from the OES raw data. When the model selecting module 105 selects the second model 106, the second model 106 may output a quality predicted result 24 of the semiconductor device using the OES data processed by applying the self-normalization, the calibration, or the intensity average ratio at time interval.

In some embodiments, the model selection module 105 may select the model to be used for inference through a performance evaluation of the first model 104 and the second model 106. In detail, the model selecting module 105 may obtain an actual quality index measured value for the wafers (e.g., 100 sheets of wafers) that were not used in the training of the first model 104 and the second model 106, and may input the OES data for the corresponding wafers to the first model 104 and the second model 106 to obtain quality index predicted values thereof. The model selection module 105 may operate coefficients of determination of the quality index measured value and the quality index predicted value, and may select the model with the larger coefficient of determination from among the first model 104 and the second model 106 as the model to be used for inference.

In detail, the model selecting module 105 may input the OES raw data to the first model 104 and the second model 106 to operate the first quality index predicted value and the second quality index predicted value, operate a first coefficient of determination based on the quality index measured value and the first quality index predicted value, and may operate a second coefficient of determination based on the actual quality index value and the second quality index predicted value. The model selection module 105 may compare sizes of the first coefficient of determination and the second coefficient of determination, may select the first model 104 as the model to be used in quality prediction when the first coefficient of determination is greater than the second coefficient of determination, and may select the second model 106 as the model to be used in quality prediction in other cases.

In some embodiments, for example, assuming one hundred sheets of wafers, the quality index measured value (T₁, . . . , T₁₀₀) may be obtained in the final test from the hundred sheets of wafers that are not used in the training when the entire processes are completed. Regarding the one hundred sheets of wafers, the corresponding OES raw data for each wafer may be input to the first model 104 and the second model 106, and the quality index predicted values for the respective models may be obtained as a result. That is, the OES raw data of the respective wafers may be input to the two models to obtain the predicted values (P_{A1}, P_{A2}, . . . , P_{A100}) of the first model 104 and the predicted values (P_{B1}, P_{B2}, . . . , P_{B100}) of the second model 106. The coefficient of determination RA of the first model 104 may be calculated according to Equation 1.

$${R}_{A} = \frac{{\sum }_{i = 1}^{100} {( {P}_{Ai} - \overline{T} )}^{2}}{{\sum }_{i = 1}^{100} {( {T}_{i} - \overline{T} )}^{2}} ( \overline{T} = \frac{1}{100} {\sum }_{i = 1}^{100} {T}_{i} ) \qquad Equation 1$$

The coefficient of determination RB of the second model 106 may be calculated according to Equation 2.

$${R}_{B} = \frac{{\sum }_{i = 1}^{100} {( {P}_{Bi} - \overline{T} )}^{2}}{{\sum }_{i = 1}^{100} {( {T}_{i} - \overline{T} )}^{2}} ( \overline{T} = \frac{1}{100} {\sum }_{i = 1}^{100} {T}_{i} ) \qquad Equation 2$$

The model selection module 105 may perform a quality prediction by comparing the coefficient of determination RA of the first model 104 and the coefficient of determination RB of the second model 106 and selecting the model with the greater value.

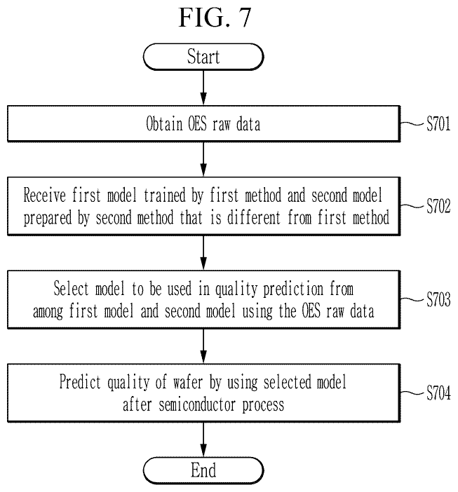

FIG. 7 shows a method for predicting quality of a semiconductor device according to one or more embodiments.

Referring to FIG. 7, the method for predicting quality of a semiconductor device may include obtaining OES raw data (S701), receiving a first model trained by a first method and a second model prepared by a second method that is different from the first method (S702), selecting a model to be used in quality prediction from among the first model and the second model using the OES raw data (S703), and predicting quality of wafer by using the selected model after the semiconductor process (S704) (e.g., by using its already-predicted quality values, which may be used in the model selecting).

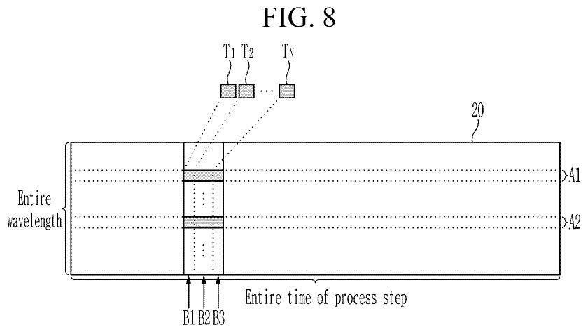

FIG. 8 shows data processing of a device for predicting quality of a semiconductor device according to one or more embodiments.

Depending on the manufacturing processes used, the etching process or the deposition process may be complicated so the sizes of the OES raw data obtained for the respective wafers may be big. In this case, the size of the OES raw data may be reduced. That is, when the OES raw data obtained for the respective wafers are big and they are grouped by selecting a specific time frame, they may be sampled at regular time intervals in a specific time frame and not in an entire specific time frame, or a moving average may be generated, which may be sampled (e.g., periodically) to minimize the loss of information of the OES raw data and reduce the size of the data.

For this purpose, the selection of the time range by the time range selecting module 102 may include determining whether the data amount belonging to the time range corresponding to the process step to be analyzed is greater than a predetermined threshold value in the OES raw data, and generating a time range by performing a sampling or a moving average on the time axis of the OES raw data when the data amount is determined to be greater than a threshold value.

Referring to FIG. 8, the device for predicting quality of a semiconductor device may obtain the OES raw data 20. The wavelength range selecting module 101 may select wavelength ranges A1 and A2 from the entire wavelength range of the OES raw data 20, as shown, based on the material used during the semiconductor process in the OES raw data 20. The time range selecting module 102 may generate time ranges B1, B2, and B3 by performing a sampling or a moving average over time (as indicated by the time axis) of the OES raw data in the obtained OES raw data 20. The token generating module 103 may generate tokens (T₁, T₂, . . . , T_{N}) by grouping the OES raw data 20 according to the wavelength ranges A1 and A2 of OES raw data selected by the wavelength range selecting module 101 and the time ranges B1, B2, and B3 of OES raw data generated and selected by the time range selecting module 102.

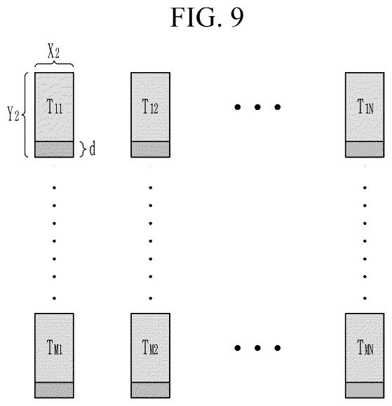

FIG. 9 shows data processing of a device for predicting quality of a semiconductor device according to one or more embodiments.

As the etching process or the deposition process performed in the region of the product being monitored or as the prediction improves, and a yield of the process increases, the OES data that is the target of analysis may be divided and analyzed in more detail to further improve yield. The grouping ranges of the wavelength axis/dimension may be increased (e.g., more or larger wavebands associated with the material are passed-through), the time axis/dimension may be grouped while further reducing equally-divided intervals (forming smaller intervals), and the grouped result may be input to the model. Hence, the OES data may be modeled in more detail (finer wavelength and/or time granularity) by including more OES intensity information caused by the OES wavelength and increasing the number of tokens with respect to time.

To this end, the device for predicting quality of a semiconductor device may obtain the yield of the process step to be analyzed, may determine whether the yield is greater than a predetermined reference value, may add an extended region (or further extend a wavelength region, e.g., from 2 nm to 4 nm) to the wavelength range corresponding to one token when the yield is determined to be greater than a predetermined reference value, may additionally divide a time section corresponding to one token into a detailed time section, and may group the OES raw data so that the one token may correspond to the wavelengths to which the extended region is added and the additionally divided time section.

Referring to FIG. 9, the tokens (T₁₁, T₁₂, . . . , T_{1N}) (N is a natural number) may be generated by grouping the OES raw data 20 according to the wavelength range A1, and the tokens (Tᵢ₁, Tᵢ₂, . . . , T_{iN}) (i=2, . . . , M) may be generated by grouping the OES raw data 20 according to the wavelength range (Ai). The tokens (T₁₁, T₂₁, . . . , T_{M1}), the tokens (T₁₂, T₂₂, . . . , T_{M2}), . . . , the tokens (T_{1N}, T_{2N}, . . . , T_{MN}) may be generated by equally dividing the time range B into predetermined time sections. The token T₁₁ may be generated to have the shape with the length of X₂ and the breadth of Y₂, and the token T₁₁ may include the OES intensity data grouped by X₂*Y₂. Compared to FIG. 3, it may be seen that the time section of the length is decreased from X₁ to X₂, and the extended region (d) is added to the breadth so the wavelength section of the breadth is increased to Y₂ from Y₁.

FIG. 10 shows a computing device according to one or more embodiments.

Referring to FIG. 10, the methods and devices for predicting quality of a semiconductor device may be realized using a computing device 50.

The computing device 50 may include at least one of a processor 510, a memory 530, a user interface input device 540, a user interface output device 550, and a storage device 560 communicating through a bus 520. The computing device 50 may include a network interface 570 electrically connected to a network 40. The network interface 570 may transmit or receive signals with other entities through the network 40.

The processor 510 may be implemented in various types such as a central processing unit (CPU), an application processor (AP), a graphic processing unit (GPU), a neural processing unit (NPU), or a micro controller unit (MCU), and may be a semiconductor device that executes instructions stored in the memory 530 or the storage device 560. The processor 510 may be configured to implement the functions and methods described above.

The memory 530 and the storage device 560 may include various forms of volatile or nonvolatile storage media. For example, the memory may include a read-only memory (ROM) 531 and a random access memory (RAM) 532. In the present embodiment, the memory 530 may be disposed inside or outside the processor 510, and the memory 530 may be connected to the processor 510 through various known means.

In some embodiments, at least some of the components or functions of the device and method for predicting quality of a semiconductor device according to the embodiments may be implemented as a program or software running on the computing device 50, and the program or software may be stored in a computer-readable medium. In detail, the computer-readable medium may be a medium on which the program for executing the steps included in the method for generating semiconductor patterns is recorded in the computer including the processor 510 for executing the programs or instructions stored in the memory 530 or the storage device 560.

In some embodiments, at least some of the components or functions of the device and method for predicting quality of a semiconductor device according to the embodiments may be implemented using hardware or circuits of the computing device 50 or may be implemented as hardware or circuit electrically connected to the computing device 50.

According to the examples described so far, the OES raw data may be used to prevent the loss or distortion of information, and the semiconductor process analysis and the quality prediction may be performed through the model that reflects the structure of the OES data including time, wavelength, and intensity, thereby increasing the quality prediction accuracy of the semiconductor devices.

Because wavelength and frequency are different domains of the same information about electromagnetic energy, all of the references here to “wavelength” are also deemed to refer to “frequency”. In particular, in the following Claims, “wavelength” also means “frequency”. Moreover, it will be appreciated that the techniques described herein are not limited to semiconductor production. Rather, the techniques may be used for producing any workpiece using OES measurements during a production process having multiple specific steps with respective sets of OES measurements.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

The computing apparatuses, the electronic devices, the processors, the memories, the sensors, the displays, the information output system and hardware, the storage devices, and other apparatuses, devices, units, modules, and components described herein with respect to FIGS. 1-10 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-10 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RW, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A method for predicting quality of a workpiece, the method comprising:
obtaining optical emission spectroscopy (OES) raw data of the workpiece, the OES raw data having a time dimension and a wavelength dimension;
selecting, in the wavelength dimension, a first portion of the OES raw data that falls within wavelength ranges selected based on a material used in a process of producing the workpiece;
selecting, in the time dimension, a second port of the OES raw data that falls within a time range corresponding to a specific step of the process, where the specific step is to be analyzed;
generating tokens by grouping the selected portions of the OES raw data; and
training a model with the tokens.

2. The method of claim 1, wherein
the selected wavelength ranges correspond to OES responsivity of the material.

3. The method of claim 1, wherein
the selecting of the first portion of the OES raw data further includes
selecting OES raw data having OES intensity greater than a predetermined reference.

4. The method of claim 1, wherein
the generating of the tokens includes
grouping the selected portions of the OES raw data by dividing the second portion of the OES data into time sections with a predetermined size.

5. The method of claim 4, wherein
the generating of the tokens includes
grouping the OES raw data so that one token corresponds to one wavelength range of the first portion of the OES raw data and corresponds to one time section of the second portion of the OES raw data.

6. The method of claim 4, wherein
the generating of the tokens includes
grouping the OES raw data so that one token corresponds to wavelength ranges of the first portion of the OES raw data and corresponds to one time section of the second portion of the OES raw data.

7. The method of claim 1, wherein
the time range is selected by
determining whether a data amount belonging to a time range corresponding to the specific step of the process to be analyzed is greater than a predetermined threshold value in the OES raw data, and
when it is determined that the data amount is greater than the threshold value, generating the second portion of the OES data by performing a sampling or a moving average in the time dimension of the OES raw data.

8. The method of claim 6, further comprising
obtaining a yield of the specific step to be analyzed, and
determining whether the yield is higher than a predetermined reference value,
wherein the generating of tokens includes
when the yield is determined to be higher than a reference value, adding an extended region to a wavelength range corresponding to one token,
additionally dividing the time section corresponding to the one token into a detailed time section, and
grouping the OES raw data so that the one token corresponds to the wavelengths to which the extended region is added and the additionally divided time section.

9. The method of claim 1, wherein
the model includes a transformer model.

10. The method of claim 1, wherein
the specific step to be analyzed includes an etching process or a deposition process.

11. A method for comprising:
obtaining optical emission spectroscopy (OES) raw data;
receiving a first model trained by a first method and a second model provided by a second method differing from the first method;
selecting a model to be used in quality prediction from among the first model and the second model by using the OES raw data; and
predicting quality of a wafer produced by a semiconductor process by using the selected model,
wherein the first model is trained by tokens generated by grouping the OES raw data according to wavelength ranges selected based on a material used in the semiconductor process and a time range selected to correspond to a specific process step of the semiconductor process, the specific process step to be analyzed during the semiconductor process.

12. The method of claim 11, wherein
the selecting of the model to be used in quality prediction includes
inputting the OES raw data to the first model and the second model to generate a first quality index predicted value and a second quality index predicted value, respectively;
generating a first coefficient of determination based on a quality index measured value and the first quality index predicted value;
generating a second coefficient of determination based on a quality index measured value and the second quality index predicted value;
comparing sizes of the first coefficient of determination and the second coefficient of determination; and
selecting the first model as the model to be used in quality prediction when the first coefficient of determination is greater than the second coefficient of determination, and selecting the second model as the model to be used in quality prediction in other cases.

13. The method of claim 11, wherein
the grouping of the OES raw data includes
dividing the time range into a time section with a predetermined size, and grouping the OES raw data so that one token corresponds to one wavelength and the time section.

14. The method of claim 11, wherein
the grouping of the OES raw data includes
dividing the time range into a time section with a predetermined size, and grouping the OES raw data so that one token corresponds to wavelengths and the time section.

15. The method of claim 11, wherein
the second model is trained using OES data processed by applying self-normalization, calibration, or an intensity average ratio at a time interval.

16. A device for predicting quality of a workpiece by executing instructions loaded on a memory device through one or more processors,
wherein the memory device provides a model based on optical emission spectroscopy (OES) raw data, and
the instructions select a subset of the OES raw data that (i) is within wavelength ranges pre-associated with a material used during a process of producing the workpiece and that (ii) is within a timespan corresponding to a specific step of the process, generates tokens according to the subset of the OES raw data, and trains the model with the tokens.

17. The device of claim 16, wherein the wavelength ranges are defined according to wavelengths of OES responsiveness of the material.

18. The device of claim 16, wherein the wavelength ranges are selected based on having intensities greater than a predetermined reference.

19. The device of claim 16, wherein
the generating of the tokens includes
dividing the time range into a time section with a predetermined size, and grouping the subset of OES raw data so that one token corresponds to one wavelength range and the time section.

20. The device of claim 16, wherein
the generating of tokens includes
dividing the time range into a time section with a predetermined size, and grouping the subset of OES raw data so that one token corresponds to wavelength ranges and the time section.
